(19) United States
(12) Patent Application Publication
(10) Pub. No.: US 2026/0310101 A1
(43) Pub. Date: Oct. 8, 2026

(54) LITHOGRAPHIC SYSTEM

(71) Applicant: ASML Netherlands B.V., Veldhoven (NL)

(72) Inventor: Wilhelmus Josephus VAN HEMMEN, Heeswijk-Dinther (NL)

(73) Assignee: ASML Netherlands B.V., Veldhoven (NL)

(21) Appl. No.: 19/481,497

(22) PCT Filed: Apr. 11, 2024
(86) PCT No.: PCT/EP2024/059909

§ 371 Date: Nov. 4, 2025

(30) Foreign Application Priority Data
May 22, 2023 (EP) 23174642.1

(51) Int. Cl. G03F 7/00

(52) U.S. Cl. CPC G03F 7/70558; G03F 7/70025; G03F 7/70033

(57) ABSTRACT

A lithographic system comprising a lithographic apparatus and a radiation source, wherein the radiation source comprises a fuel emitter operable to provide a fuel target at a plasma formation region and further comprises a laser system operable to provide a laser beam which is incident on the fuel target to generate EUV radiation which is used to expose substrates, wherein the laser system comprises a seed laser and a laser beam amplification system comprising a series of optical amplifiers and a controller, wherein the controller is configured to operate the final optical amplifier of the series at a power level less than a maximum power level of the final optical amplifier during exposure of an exposure area of a substrate.

### CROSS-REFERENCE TO RELATED APPLICATIONS

This application claims priority of EP application 23174642.1 which was filed on 22nd May 2023, and which is incorporated herein in its entirety by reference.

### FIELD

The present invention relates to a lithographic system. The lithographic system may comprise an extreme ultraviolet (EUV) radiation source an a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

EUV radiation for a lithographic apparatus may be produced by a laser produced plasma (LPP) radiation source. Within an LPP radiation source, a laser beam provided by a laser system may be used to irradiate fuel droplets so as to produce a plasma which will emit EUV radiation.

It is desirable that the laser beam which is used to illuminate the fuel droplets has a high power. A laser beam amplification system amplifies the laser beam to provide this high power. The laser beam amplification system may use a considerable amount of energy.

It may be desirable to provide a laser beam amplification system which address the issue of high energy consumption, or a problem associated with the prior art, in a manner which is not disclosed or suggested by the prior art.

### SUMMARY

According to a first aspect of the invention there is provided a lithographic system comprising a lithographic apparatus and a radiation source, wherein the radiation source comprises a fuel emitter operable to provide a fuel target at a plasma formation region and further comprises a laser system operable to provide a laser beam which is incident on the fuel target to generate EUV radiation which is used to expose substrates, wherein the laser system comprises a seed laser and a laser beam amplification system comprising a series of optical amplifiers and a controller, wherein the controller is configured to operate the final optical amplifier of the series at a power level less than a maximum power level of the final optical amplifier during exposure of an exposure area of a substrate.

Advantageously, by operating the final optical amplifier at a power level less than a maximum power level of the final optical amplifier, the efficiency with which the laser beam is amplified is improved (compared with if the final optical amplifier were operating at its maximum power level).

The controller may be configured to operate the final optical amplifier of the series at a power level, relative to the maximum power level, that is lower than power levels, relative to respective maximum power levels, of the other optical amplifiers of the series.

The laser beam amplification system may comprise four optical amplifiers.

The controller may be configured to operate the final optical amplifier at less than 90% of the maximum power level of the final optical amplifier during exposure of the exposure area.

The controller may be configured to operate the final optical amplifier at less than 80% of the maximum power of the final optical amplifier during exposure of the exposure area.

The controller may be further configured to operate a penultimate optical amplifier of the series at a power level less than 100% of a maximum power level during exposure of the exposure area.

The controller may be configured to operate the penultimate optical amplifier of the series at a power level, relative to the maximum power level, that is lower than power levels, relative to respective maximum power levels, of upstream optical amplifiers of the series during exposure of the exposure area.

The controller may be configured to adjust the power levels of the optical amplifiers of the series in unison.

The controller may be configured to modulate the power level of the final optical amplifier of the series based upon a power of the amplified laser beam output from the final optical amplifier and/or based on a power of EUV radiation provided by the radiation source.

The controller may be configured to modulate the power level of each of the optical amplifiers of the series based upon the power of the amplified laser beam output from the final optical amplifier.

The lithographic system may further comprise an optical detector which is configured to provide an output indicative of a power of the amplified laser beam output from the final optical amplifier.

The controller may be configured to further reduce power delivered to the final optical amplifier of the series when the substrate is not being exposed.

According to a second aspect of the invention there is provided a lithographic system comprising a lithographic apparatus and a radiation source, wherein the radiation source comprises a fuel emitter operable to provide a fuel target at a plasma formation region and further comprises a laser system operable to provide a laser beam which is incident on the fuel target to generate EUV radiation which is used to expose substrates, wherein the laser system comprises a seed laser and a laser beam amplification system comprising a series of optical amplifiers and a controller, wherein the controller is configured to operate the final optical amplifier of the series at a power level, relative to a maximum power level, that is lower than power levels, relative to respective maximum power levels, of the other optical amplifiers of the series.

Advantageously, by operating the final optical amplifier at a power level, relative to a maximum power level, that is lower than power levels, relative to respective maximum power levels, of the other optical amplifiers of the series, efficiency is improved. This may apply during exposure of an exposure area and may apply when an exposure area is not being exposed.

The controller may be configured to operate the final optical amplifier at the lower power level during exposure of an exposure area of a substrate

The controller may be configured to operate a penultimate optical amplifier of the series at a power level, relative to a maximum power level, that is lower than power levels, relative to respective maximum power levels, of upstream optical amplifiers of the series.

The controller may be configured to operate the penultimate optical amplifier at the lower power level during exposure of an exposure area of a substrate

According to a third aspect of the invention, there is provided a method of amplifying a laser beam used to generate EUV radiation during exposure of an exposure area of a substrate, the method comprising receiving a laser beam and amplifying the laser beam using a series of optical amplifiers, wherein a final optical amplifier of the series is operated at a power level less than a maximum power level of the final optical amplifier.

Advantageously, this may provide an improvement of efficiency.

According to a fourth aspect of the invention, there is provided a method of amplifying a laser beam used to generate EUV radiation, the method comprising receiving a laser beam and amplifying the laser beam using a series of optical amplifiers, wherein a final optical amplifier of the series is operated at a power level, relative to a maximum power level, that is lower than power levels, relative to respective maximum power levels, of the other optical amplifiers of the series.

Advantageously, this may provide an improvement of efficiency.

Features of different aspects of the invention may be combined together.

### BRIEF DESCRIPTION OF THE DRAWINGS

Embodiments of the invention will now be described, by way of example only, with reference to the accompanying schematic drawings, in which:

FIG. 1 schematically depicts a lithographic system comprising a lithographic apparatus and a radiation source according to an embodiment of the invention;

FIG. 2 schematically depicts a laser system which forms part of an embodiment of the invention;

FIG. 3 schematically depicts operation of a laser beam amplification system according to an embodiment of the invention;

FIG. 4 schematically depicts operation of a laser beam amplification system according to another embodiment of the invention; and

FIG. 5 schematically depicts operation of a laser beam amplification system according to another embodiment of the invention;

### DETAILED DESCRIPTION

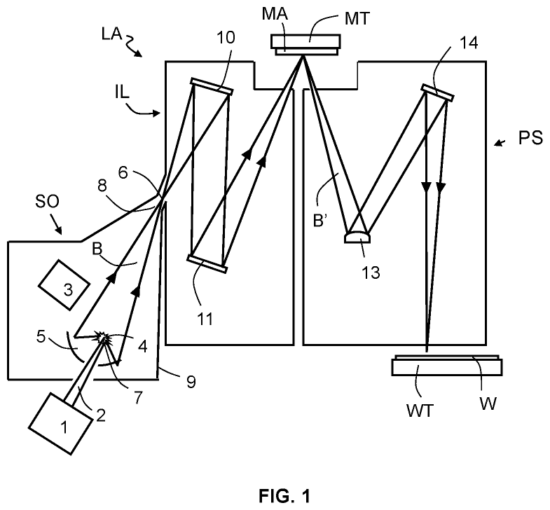

FIG. 1 shows a lithographic system according to an embodiment of the disclosure. The lithographic system comprises a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13, 14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. The radiation source includes a laser system 1 according to an embodiment of the disclosure. The laser system 1, which may, for example, include a CO₂ laser, is arranged to deposit energy via a pulsed laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser pulsed beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The pulsed laser beam 2 which is incident upon the tin at the plasma formation region 4 may be referred to as a main laser beam or main pulsed laser beam. Individual pulses of this pulsed laser beam 2 may be referred to as main pulses.

Before the main laser beam 2 is incident upon the tin at the plasma formation region 4, another pre-pulse laser beam may be incident on the tin. The pre-pulse laser beam may act to change a shape of the tin so as to increase the conversion efficiency when the main pulse is (subsequently) incident on the tin. One or more additional pulses may be used. The pre-pulse laser beam and the one or more additional pulses may for example be provided by different lasers. The pre-pulse laser beam and the one or more additional pulses may travel along a beam path or paths which is different to a beam path of the main laser beam.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the main laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

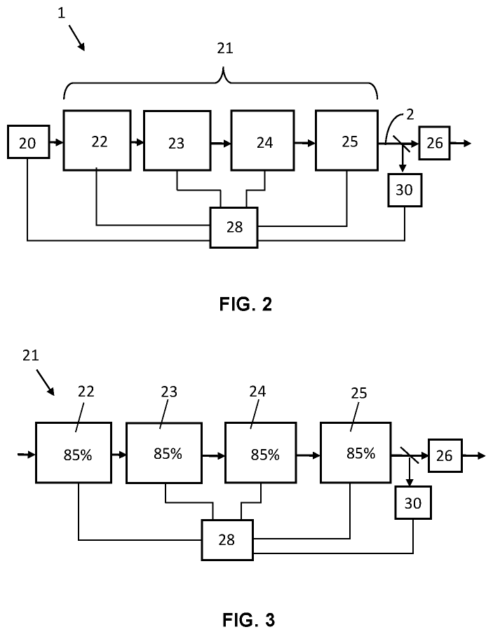

The laser system 1 comprises a seed laser system 20 and a laser beam amplification system 21 according to an embodiment of the disclosure, as schematically depicted in FIG. 2. A beam steering system 26 which may deliver the resulting main laser beam 2 to the plasma formation region 4 (see FIG. 1) is also depicted.

The seed laser system 20 provides seed laser pulses to the laser beam amplification system 21. The laser beam amplification system 21 comprises four optical amplifiers 22-25 and a controller 28. The optical amplifiers 22-25 may alternatively be referred to as laser beam amplifiers or optical amplifiers. The optical amplifiers 22-25 are provided in series such that a first optical amplifier 22 amplifies a laser beam output by the seed laser system 20, the second optical amplifier 23 provides further amplification to the laser beam output from the first optical amplifier 22, the third optical amplifier 24 provides further amplification to the amplified laser beam output from the second optical amplifier 23, and the fourth optical amplifier 25 provides further amplification to the laser beam output from the third optical amplifier 24. Thus, four amplification stages are applied to the laser beam by the four optical amplifiers 22-25, the amplification stages being provided in series and each increasing the power of the laser beam. The laser beam output from the fourth and final optical amplifier 25 passes to a beam steering system 26. The beam steering system 26 steers the amplified laser beam to the plasma formation region 4 (see FIG. 1), where the amplified laser beam is incident upon fuel droplets and thereby generates EUV radiation. The amplified laser beam is a pulsed laser beam, and may be referred to as a main pulse laser beam 2.

A controller 28 controls the power provided to the optical amplifier 22-25. The controller 28 may also control the power of the laser beam output from the seed laser system 20. The controller may be configured to separately adjust the power provided to each optical amplifier 22-25. An optical sensor 30 receives a portion of the amplified laser beam 2 and provides an output signal which indicates the power of the amplified laser beam. The controller 28 modulates the power provided to the optical amplifier 22-25. The modulation may be based upon the output signal provided by the optical sensor 30 (or a different sensor), for example with reference to a desired value. For example, an EUV radiation source controller may issue a command requesting a desired power of the main pulse laser beam 2. The modulation applied by the controller 28 may attempt to maintain the power of the main pulse laser beam 2 at that desired power. The EUV radiation source may use an EUV sensor to determine the desired power of the main pulse laser beam 2 that is requested. The controller 28 may also modulate the power supplied to the seed laser system 20 in response to a requested desired power. Modulation of the power provided to the seed laser system 20 and of the power provided to the optical amplifiers 22-25 may occur simultaneously.

In embodiment (not depicted), an optical sensor may be provided between the penultimate optical amplifier 24 and the final optical amplifier 25. Where this is the case, an output provided from the optical sensor may be adjusted to take into account a power level which is provided to the final optical amplifier 25. The adjustment may convert the output from the optical sensor to a value which indicates the power of the amplified laser beam output from the final optical amplifier 25.

Although four optical amplifiers 22-25 are depicted in FIG. 2, a different number of optical amplifiers may be provided. In general, a series of optical amplifiers may be provided.

FIG. 3 schematically depicts operation of the laser beam amplification system 21 according to an embodiment of the invention. The laser beam amplification system 21 amplifies a laser beam emitted by the seed laser system 20 (see FIG. 2), to meet requirements of the lithographic apparatus LA (see FIG. 1). During operation of the lithographic apparatus LA, the radiation beam B is projected onto an exposure area on the substrate W. The substrate W is then moved to a different position such that a different exposure area on the substrate can be receive the patterned radiation beam B. During this movement between different exposure areas of the substrate W, the radiation beam B continues to be provided by the radiation source SO. Masking blades (not depicted) provided adjacent to the patterning device MA are closed during this movement of the substrate W, thereby blocking the radiation beam B such that it is not incident upon the substrate W. The masking blades are opened when the substrate W has been moved into position for the exposure of the next exposure area of the substrate.

During exposure of an exposure area on the substrate it may be desirable to provide the EUV radiation beam B at a high power. This is because a high power allows the substrate to be exposed more quickly than if a lower power were to be used, thereby providing a higher throughput of the lithographic apparatus LA than if a lower power were to be used. When an exposure area is not being exposed, it may be desirable to operate the radiation source SO at a lower power. This may reduce power consumption of the source, and may improve power stability of the source when exposure of a next exposure area begins).

Although it may be desirable to provide the EUV radiation beam at high power during exposure of an exposure area, the power of the EUV radiation beam may be less than a maximum possible power. Similarly, the power of the main pulse laser beam 2 may be less than a maximum possible power. There are various possible reasons for this. One possible reason is that, in order to allow the controller 28 to adjust the power of the main pulse laser beam 2 to attempt to maintain the power at a desired value, some scope to increase the power of the main pulse laser beam is needed. Thus, the main pulse laser beam 2 should not be at a maximum possible power, in order to allow such increases to take place. Another possible reason is that it may be desirable to expose an exposure area with a power which is below the maximum possible power. This may be for example due to requirements of a specific lithographic recipe, or when applying a second exposure to a previously exposed area in order to correct for a previous exposure error.

In an embodiment of the invention, the final optical amplifier 25 of the series of optical amplifiers operates at less than 100% of a maximum power level of the final optical amplifier during exposure of a substrate exposure area. An improvement in overall efficiency of the laser beam amplification system 21 is obtained when the final optical amplifier 25 is operated at a power level which is below its maximum power level. Overall efficiency may be considered to relate to the power consumption of the laser beam amplification system 21. Power consumption may be referred to as wall plug power. An improvement of overall efficiency corresponds with a reduction of wall plug power needed in order to obtain a given power of main pulse laser beam 2.

In an embodiment of the invention, the final optical amplifier 25 of the series of optical amplifiers operates at less than 90% of a maximum power level of the final optical amplifier during exposure of a substrate exposure area. In an embodiment of the invention, the final optical amplifier 25 of the series of optical amplifiers operates at less than 80% of a maximum power level of the final optical amplifier during exposure of a substrate exposure area.

In the embodiment of FIG. 3, the four optical amplifiers 22-25 all operate at for example 85% of their maximum power level during exposure of a substrate exposure area. The sensor 30 provides an output signal which indicates the power of the laser beam 2 output from the final optical amplifier 25. This output signal is provided to the controller 28. The controller 28 modulates a power provided to each optical amplifier 22-25 based upon the output signal provided by the optical sensor 30. Thus, a feedback loop is provided in which the power provided to the optical amplifier 22-25 is modulated based upon the output from the optical sensor 30. In the embodiment of FIG. 3, each of the optical amplifiers 22-25 operates at the same power level. In other words, the controller 28 increases and decreases the power level at which the optical amplifiers 22-25 operate in a synchronized manner.

The power levels referred to in connection with FIG. 3 (and other figures) are not absolute values, but instead are percentages which indicate the power level relative to a maximum power level that at which each optical amplifier 22-25 can operate. The maximum power level of an optical amplifier is determined by physical characteristics of the optical amplifier. For example, the optical amplifiers 22-25 may be CO₂ gas optical amplifiers. The power provided to the CO₂ gas optical amplifiers may comprise RF power provided to electrodes. The RF power excites the CO₂ gas, providing energy to the CO₂ gas which is then transferred to the laser beam (amplifying the laser beam). A maximum power level of a CO₂ gas optical amplifier is reached when providing additional power to the optical amplifier will not provide any more amplification of the laser beam (a population inversion of the CO₂ gas cannot be further increased). In general, a maximum power level of an optical amplifier may be interpreted as meaning a power level provided to the optical amplifier which provides maximum amplification of a laser beam (i.e. further increasing the power provided to the optical amplifier will not provide additional amplification of the laser beam).

The absolute powers provided to each of the optical amplifiers 22-25 may differ. For example, the maximum power that can be provided to the last optical amplifier 25 may be greater than the maximum power that can be provided to the first optical amplifier 22. The last optical amplifier 25 may be configured to use more power than the first optical amplifier 22 because the power of the laser beam which is to be amplified by the last optical amplifier is much greater than the power of the laser beam when it is amplified by the first optical amplifier. In one example, the maximum power level (e.g. RF power) at which each of the optical amplifiers operates is: 50 kW for the first optical amplifier 22, 86 kW for the second optical amplifier 23, 116 kW for the penultimate optical amplifier 24, and 140 kW for the final optical amplifier 25. The wall plug power provided to the optical amplifiers may be greater than these powers because conversion to RF power (or power of a different gain medium) is not 100% efficient. For example, conversion to RF power may have an efficiency of around 80%, meaning that the wall plug power provided to the optical amplifiers may be around 20% greater than the RF power values.

Although FIG. 3 depicts the optical amplifiers 22-25 as operating at 85% of their maximum power level, the optical amplifiers may be operated at different power levels. In general, the optical amplifiers 22-25 may be operated at less than 90% of their maximum power level on average (during exposure of a substrate exposure area). The optical amplifiers may for example operate at between 80% and 90% of their maximum power level on average (during exposure of a substrate exposure area).

In the embodiment of FIG. 3, the controller 28 adjusts the power levels of the optical amplifiers 22-25 in unison. The power levels at which the optical amplifiers 22-25 operate may be changed by the controller 28, but any changes apply to all of the optical amplifiers together.

In other embodiments, the controller may adjust the power levels of the optical amplifiers 22-25 separately.

In some embodiments, the power level at which final optical amplifier operates (relative to its maximum power level) may be lower than the power levels at which the other optical amplifiers operate (relative to their maximum power levels). This may provide an improvement of the overall efficiency of the laser beam amplification system 21. The improvement of efficiency may apply during exposure of a substrate exposure area. An improvement of efficiency may also apply between exposures of substrate exposure areas.

In some embodiments, the power level at which the penultimate optical amplifier operates (relative to its maximum power) may be lower than the power levels at which upstream optical amplifiers operate (relative to their maximum powers). This may provide a further improvement of the overall efficiency of the laser beam amplification system 21. The improvement of efficiency may apply during exposure of a substrate exposure area. An improvement of efficiency may also apply between exposures of substrate exposure areas.

The power level of the final optical amplifier 25, and optionally other optical amplifiers 22-24 may be modulated based upon a signal received from the optical detector 30. That is, a feedback loop may be formed which uses the optical detector 30 and controls the power level of the final optical amplifier 25 (and optionally other optical amplifiers 22-24). The feedback loop may be configured to provide a desired power level of laser beam 2, and may compensate for example for fluctuations of the power of the radiation beam B during an exposure of a substrate exposure area.

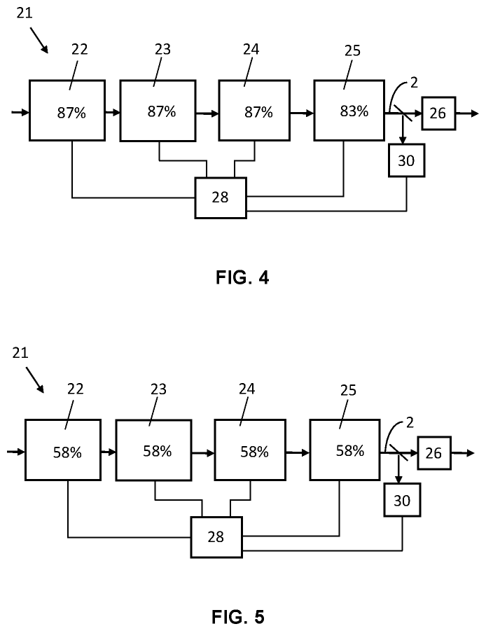

An alternative embodiment is schematically depicted in FIG. 4. In this embodiment the first, second and third optical amplifiers 22-24 are all operating at 87% of their maximum power level (during exposure of a substrate exposure area). The final optical amplifier 25 is operating at 83% of its maximum power level. The power levels indicated in FIG. 4 may be average power levels, and the power levels may be modulated based upon a feedback signal provided by the optical sensor 30 (the same may apply to other embodiments). The power levels of the optical amplifiers 22-25 are controlled by the controller 28.

In this embodiment the final optical amplifier 25 of the series of optical amplifiers operates at a lower power level than the other optical amplifiers 22-24 of the series. The power level values shown in FIG. 4 are merely examples, and other power levels may be used. In general, the power level at which the final optical amplifier 25 operates may be lower than the power level at which other optical amplifiers 22-24 of the series operate. This may provide an improvement of overall efficiency of the laser beam amplification system 21.

The power level at which the penultimate optical amplifier 24 operates may be lower than the power level at which upstream optical amplifiers 22, 23 of the series operate. This may provide a further improvement of overall efficiency of the laser beam amplification system 21.

In a conventional arrangement, the power level of the final optical amplifier 25 of the series is set at 100% during exposure of a substrate exposure area. This approach has been taken because there was an understanding that modulating the power level of the final optical amplifier 25 was likely to cause power instability in the laser beam 2 provided to the EUV radiation source SO, and thus cause instability in the EUV radiation beam B itself. However, it has surprisingly now been found that operating the final optical amplifier 25 at a power level of less than 100% does not introduce power instability into the laser beam 2.

In an embodiment, the radiation source SO further comprises at least one additional laser (not depicted) configured to provide a pulse which is incident upon the fuel droplet before the main laser beam pulse. This additional pulse may be referred to as a pre-pulse. The pre-pulse is delivered to the plasma formation region 4 via a beam path which does not include the optical amplifier series 22-25. In a conventional radiation source, the pre-pulse travels through an optical amplifier series, and this complicates operation of the optical amplifiers, and can accentuate instability of the power of the main laser beam when the final optical amplifier is operated at a power level below its maximum power level. However, in some embodiments of the invention, because the pre-pulse does not pass through the optical amplifier series 22-25, instability of the power of the laser beam which might otherwise have occurred when operating the final optical amplifier 25 below its maximum power level does not occur.

In an embodiment, the power provided to one or more of the optical amplifiers 22-25 may be reduced when a substrate exposure area is not being exposed (e.g. when moving the substrate between exposure areas). An example of this is depicted in FIG. 5. In FIG. 5, each of the optical amplifiers 22-25 is operated at 58% of its maximum power level when exposure of a substrate exposure area is not taking place. The power levels of the optical amplifiers 22-25 are controlled by the controller 28, which receives a signal from the lithographic apparatus LA indicating that exposure of a substrate exposure area is not taking place.

The value 58% is merely an example, and the optical amplifiers 22-25 may be operated at other power levels. In general, the power levels of the optical amplifiers 22-25 may be less than 65% of the maximum power levels of the optical amplifiers when a substrate exposure area is not being exposed. The power levels may be less than 60% of the maximum power levels. Different optical amplifiers 22-25 may be operated at different power levels. The final optical amplifier may be operated at a power level which is equal to or lower than the power level of other optical amplifiers.

It has been found that an improvement in overall efficiency of the laser beam amplification system 21 is obtained when the final optical amplifier 25 is operated at a power level which is below its maximum power level. Since the optical amplifiers 22-25 use a considerable amount of power, this improvement in efficiency provides a significant cost saving. It has surprisingly been found that doing this does not cause significant instability of the power of the laser beam to outputs from the series of optical amplifiers 22-25.

It has further been found that a further improvement in overall efficiency of the laser beam amplification system 21 may be obtained when the penultimate optical amplifier 24 is operated at a power level which is below its maximum power level. This improvement in efficiency also provides a significant cost saving.

In general, the overall efficiency of the laser beam amplification system 21 is achieved when operating the final optical amplifier 25 below its maximum power level, and optionally operating the penultimate optical amplifier 24 below its maximum power level.

Embodiments of the invention may provide a power saving of at least 20 kW. Embodiment of the invention may provide a power saving of 40 kW or more.

In some embodiments one or more pre-pulses may pass through the optical amplifier series 22-25. Where this is the case, it may be more difficult to control stability of the power of the amplified main laser beam 2.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatuses may be generally referred to as lithographic tools. Such a lithographic tool may use vacuum conditions or ambient (non-vacuum) conditions.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the clauses and claims set out below.

### Clauses

1. A lithographic system comprising a lithographic apparatus and a radiation source, wherein the radiation source comprises a fuel emitter operable to provide a fuel target at a plasma formation region and further comprises a laser system operable to provide a laser beam which is incident on the fuel target to generate EUV radiation which is used to expose substrates;
   wherein the laser system comprises a seed laser and a laser beam amplification system comprising a series of optical amplifiers and a controller, wherein the controller is configured to operate the final optical amplifier of the series at a power level less than a maximum power level of the final optical amplifier during exposure of an exposure area of a substrate.
2. The lithographic system of clause 1, wherein the controller is configured to operate the final optical amplifier of the series at a power level, relative to the maximum power level, that is lower than power levels, relative to respective maximum power levels, of the other optical amplifiers of the series.
3. The lithographic system of clause 1 or clause 2, wherein the laser beam amplification system comprises four optical amplifiers.
4. The lithographic system of any preceding clause, wherein the controller is configured to operate the final optical amplifier at less than 90% of the maximum power level of the final optical amplifier during exposure of the exposure area.
5. The lithographic system of any preceding clause, wherein the controller is configured to operate the final optical amplifier at less than 80% of the maximum power of the final optical amplifier during exposure of the exposure area.
6. The lithographic system of any preceding clause, wherein the controller is further configured to operate a penultimate optical amplifier of the series at a power level less than 100% of a maximum power level during exposure of the exposure area.
7. The lithographic system of clause 6, wherein the controller is configured to operate the penultimate optical amplifier of the series at a power level, relative to the maximum power level, that is lower than power levels, relative to respective maximum power levels, of upstream optical amplifiers of the series during exposure of the exposure area.
8. The lithographic system of any preceding clause, wherein the controller is configured to adjust the power levels of the optical amplifiers of the series in unison.
9. The lithographic system of any preceding clause, wherein the controller is configured to modulate the power level of the final optical amplifier of the series based upon a power of the amplified laser beam output from the final optical amplifier and/or based on a power of EUV radiation provided by the radiation source.
10. The lithographic system of clause 7, wherein the controller is configured to modulate the power level of each of the optical amplifiers of the series based upon the power of the amplified laser beam output from the final optical amplifier.
11. The lithographic system of any preceding clause, further comprising an optical detector which is configured to provide an output indicative of a power of the amplified laser beam output from the final optical amplifier.
12. The lithographic system of any preceding clause, wherein the controller is configured to further reduce power delivered to the final optical amplifier of the series when the substrate is not being exposed.
13. A lithographic system comprising a lithographic apparatus and a radiation source, wherein the radiation source comprises a fuel emitter operable to provide a fuel target at a plasma formation region and further comprises a laser system operable to provide a laser beam which is incident on the fuel target to generate EUV radiation which is used to expose substrates;
   wherein the laser system comprises a seed laser and a laser beam amplification system comprising a series of optical amplifiers and a controller, wherein the controller is configured to operate the final optical amplifier of the series at a power level, relative to a maximum power level, that is lower than power levels, relative to respective maximum power levels, of the other optical amplifiers of the series.
14. The lithographic system of clause 13, wherein the controller is configured to operate the final optical amplifier at the lower power level during exposure of an exposure area of a substrate
15. The lithographic system of clause 13 or clause 14, wherein the controller is configured to operate a penultimate optical amplifier of the series at a power level, relative to a maximum power level, that is lower than power levels, relative to respective maximum power levels, of upstream optical amplifiers of the series.
16. The lithographic system of clause 15, wherein the controller is configured to operate the penultimate optical amplifier at the lower power level during exposure of an exposure area of a substrate
17. A method of amplifying a laser beam used to generate EUV radiation during exposure of an exposure area of a substrate, the method comprising receiving a laser beam and amplifying the laser beam using a series of optical amplifiers, wherein a final optical amplifier of the series is operated at a power level less than a maximum power level of the final optical amplifier.
18. A method of amplifying a laser beam used to generate EUV radiation, the method comprising receiving a laser beam and amplifying the laser beam using a series of optical amplifiers, wherein a final optical amplifier of the series is operated at a power level, relative to a maximum power level, that is lower than power levels, relative to respective maximum power levels, of the other optical amplifiers of the series.

1-16. (canceled)

17. A lithographic system comprising:
a lithographic apparatus;
a radiation source comprising a fuel emitter operable to provide a fuel target at a plasma formation region; and
a laser system operable to provide a laser beam which is incident on the fuel target to generate EUV radiation which is used to expose substrates, wherein the laser system comprises:
a seed laser, and
a laser beam amplification system comprising a series of optical amplifiers and a controller,
wherein the controller is configured to operate a final optical amplifier of the series of optical amplifiers at a power level less than a maximum power level of the final optical amplifier during exposure of an exposure area of a substrate.

18. The lithographic system of claim 17, wherein the controller is configured to operate the final optical amplifier of the series at a power level, relative to the maximum power level, that is lower than power levels, relative to respective maximum power levels, of other optical amplifiers of the series.

19. The lithographic system of claim 17, wherein the controller is configured to operate the final optical amplifier at less than 90% or at less than 80% of the maximum power level of the final optical amplifier during exposure of the exposure area.

20. The lithographic system of claim 17, wherein the controller is further configured to operate a penultimate optical amplifier of the series at a power level less than 100% of a maximum power level during exposure of the exposure area.

21. The lithographic system of claim 20, wherein the controller is configured to operate the penultimate optical amplifier of the series at a power level, relative to the maximum power level, that is lower than power levels, relative to respective maximum power levels, of upstream optical amplifiers of the series during exposure of the exposure area.

22. The lithographic system of claim 17, wherein the controller is configured to adjust the power levels of the optical amplifiers of the series in unison.

23. The lithographic system of claim 17, wherein the controller is configured to modulate the power level of the final optical amplifier of the series based upon a power of the amplified laser beam output from the final optical amplifier and/or based on a power of EUV radiation provided by the radiation source.

24. The lithographic system of claim 21, wherein the controller is configured to modulate the power level of each of the optical amplifiers of the series based upon the power of the amplified laser beam output from the final optical amplifier.

25. The lithographic system of claim 21, further comprising an optical detector which is configured to provide an output indicative of a power of the amplified laser beam output from the final optical amplifier.

26. The lithographic system of claim 17, wherein the controller is configured to further reduce power delivered to the final optical amplifier of the series when the substrate is not being exposed.

27. A lithographic system comprising:
a lithographic apparatus;
a radiation source comprising a fuel emitter operable to provide a fuel target at a plasma formation region; and
a laser system operable to provide a laser beam which is incident on the fuel target to generate EUV radiation which is used to expose substrates, wherein the laser system comprises:
a seed laser, and
a laser beam amplification system comprising a series of optical amplifiers and a controller,
wherein the controller is configured to operate a final optical amplifier of the series at a power level, relative to a maximum power level, that is lower than power levels, relative to respective maximum power levels, of other optical amplifiers of the series.

28. The lithographic system of claim 27, wherein the controller is configured to operate the final optical amplifier at the lower power level during exposure of an exposure area of a substrate

29. The lithographic system of claim 27, wherein the controller is configured to operate a penultimate optical amplifier of the series at a power level, relative to a maximum power level, that is lower than power levels, relative to respective maximum power levels, of upstream optical amplifiers of the series.

30. The lithographic system of claim 29, wherein the controller is configured to operate the penultimate optical amplifier at the lower power level during exposure of an exposure area of a substrate

31. A method of amplifying a laser beam used to generate EUV radiation during exposure of an exposure area of a substrate, the method comprising:
receiving a laser beam;
amplifying the laser beam using a series of optical amplifiers; and
operating a final optical amplifier of the series at a power level less than a maximum power level of the final optical amplifier.

32. A method of amplifying a laser beam used to generate EUV radiation, the method comprising:
receiving a laser beam;
amplifying the laser beam using a series of optical amplifiers; and
operating a final optical amplifier of the series at a power level, relative to a maximum power level, that is lower than power levels, relative to respective maximum power levels, of other optical amplifiers of the series.
